(19) United States
(12) Patent Application Publication
(10) Pub. No.: US 2025/0015756 A1
(43) Pub. Date: Jan. 9, 2025

(54) Electrically Isolated Heat Dissipating Junction Box

(71) Applicant: Solaredge Technologies Ltd., Herzeliya (IL)

(72) Inventors: Guy Sella, Bitan Aharon (IL); Lior Handelsman, Givatayim (IL); Vadim Shmukler, Rishon-Lezion (IL); Meir Adest, Modiin (IL); Meir Gazit, Ashkelon (IL); Yoav Galin, Raanana (IL)

(21) Appl. No.: 18/775,160

(22) Filed: Jul. 17, 2024

Related U.S. Application Data
(63) Continuation of application No. 18/320,581, filed on May 19, 2023, now Pat. No. 12,074,566.
Application No. 18/320,581 is a continuation of application No. 17/971,825, filed on Oct. 24, 2022, now Pat. No. 11,695,371.
Application No. 17/971,825 is a continuation of application No. 17/097,613, filed on Nov. 13, 2020, now Pat. No. 11,509,263.
Application No. 17/097,613 is a continuation of application No. 16/871,117, filed on May 11, 2020, now Pat. No. 10,879,840.
Application No. 16/871,117 is a continuation of application No. 16/524,601, filed on Jul. 29, 2019, now Pat. No. 10,686,402.
Application No. 16/524,601 is a continuation of application No. 15/651,134, filed on Jul. 17, 2017, now Pat. No. 10,411,644.
Application No. 15/651,134 is a continuation of application No. 14/997,079, filed on Jan. 15, 2016, now Pat. No. 9,748,897.
Application No. 14/997,079 is a continuation of application No. 14/641,690, filed on Mar. 9, 2015, now Pat. No. 9,748,896.
Application No. 14/641,690 is a continuation of application No. 13/901,706, filed on May 24, 2013, now Pat. No. 9,006,569.
Application No. 13/901,706 is a continuation of application No. 12/785,773, filed on May 24, 2010, now Pat. No. 8,476,524.
(60) Provisional application No. 61/180,455, filed on May 22, 2009.

(51) Int. Cl. H02S 40/34; G08B 13/14; H02G 15/10; H05K 5/02; H05K 5/06; H05K 7/20; H05K 9/00

(52) U.S. Cl. CPC H02S 40/34; G08B 13/1409; H02G 15/10; H02S 40/345; H05K 5/02; H05K 5/062; H05K 7/2039; H05K 9/0007; H05K 9/0009; H05K 9/0015; Y10S 248/906; Y10T 29/49117

(57) ABSTRACT

A junction box used for making electrical connections to a photovoltaic panel. The junction box has two chambers including a first chamber and a second chamber and a wall common to and separating both chambers. The wall may be adapted to have an electrical connection therethrough. The two lids are adapted to seal respectively the two chambers. The two lids are on opposite sides of the junction box relative to the photovoltaic panel. The two lids may be attachable using different sealing processes to a different level of hermeticity. The first chamber may be adapted to receive a circuit board for electrical power conversion. The junction box may include supports for mounting a printed circuit board in the first chamber. The second chamber is configured for electrical connection to the photovoltaic panel. A metal heat sink may be bonded inside the first chamber.

### CROSS REFERENCE TO RELATED APPLICATIONS

This application is a continuation of U.S. patent application Ser. No. 18/320,581, filed May 19, 2023, which is a continuation of U.S. patent application Ser. No. 17/971,825, filed Oct. 24, 2022 (now U.S. Pat. No. 11,695,371), which is a continuation of U.S. patent application Ser. No. 17/097,613 filed Nov. 13, 2020 (now U.S. Pat. No. 11,509,263), which is a continuation of U.S. patent application Ser. No. 16/871,117 filed May 11, 2020 (now U.S. Pat. No. 10,879,840), which is a continuation of U.S. patent application Ser. No. 16/524,601 filed Jul. 29, 2019 (now U.S. Pat. No. 10,686,402), which is a continuation of U.S. patent application Ser. No. 15/651,134 filed Jul. 17, 2017 (now U.S. Pat. No. 10,411,644), which is a continuation of U.S. patent application Ser. No. 14/997,079 filed Jan. 15, 2016 (now U.S. Pat. No. 9,748,897), which is a continuation of 14/641,690 filed Mar. 9, 2015 (now U.S. Pat. No. 9,748,896), which is a continuation of U.S. patent application Ser. No. 13/901,706 filed May 24, 2013 (now U.S. Pat. No. 9,006,569), which is a continuation of U.S. patent application Ser. No. 12/785,773 filed May 24, 2010 (now U.S. Pat. No. 8,476,524), which claims benefit from U.S. patent application 61/180,455 filed May 22, 2009. The disclosures of the above-identified applications are incorporated herein by reference for all purposes.

### BACKGROUND

### 1. Technical Field

The present invention relates to a junction box for power sources, and specifically to a junction box for electrically connecting to a photovoltaic panel.

### 2. Description of Related Art

A photovoltaic module or photovoltaic panel is a packaged interconnected assembly of photovoltaic cells, also known as solar cells. Since a single photovoltaic module can only produce a limited amount of power, commercial installations include several modules or panels interconnected in serial and in parallel into a photovoltaic array. Electrical connections are made in series to achieve a desired output voltage and/or in parallel to provide a desired amount of current source capability. A photovoltaic installation typically includes the array of photovoltaic modules, an inverter, batteries and interconnection wiring.

When part of a photovoltaic module is shaded, the shaded cells do not produce as much current as the unshaded cells. Since photovoltaic cells are connected in series, the same amount of current must flow through every serially connected cell. The unshaded cells force the shaded cells to pass more current. The only way the shaded cells can operate at a higher current is to operate in a region of negative voltage that is to cause a net voltage loss to the system. The current times this negative voltage gives the negative power produced by the shaded cells. The shaded cells dissipate power as heat and cause “hot spots”. Bypass diodes are therefore integrated with the photovoltaic modules to avoid overheating of cells in case of partial shading of the photovoltaic module.

Blocking diodes may be placed in series with cells or modules to block reverse leakage current backwards through the modules such as to block reverse flow of current from a battery through the module at night or to block reverse flow down damaged modules from parallel-connected modules during the day.

Electronic modules may be integrated with the photovoltaic modules which perform electrical conversion, e.g. direct current (DC) to direct current conversion, electrical inversion, e.g. micro-inverter, or other functions such as monitoring of performance and/or protection against theft.

U.S. Pat. No. 7,291,036 discloses a photovoltaic connection system including a connection box with for surface mounted diodes mounted on a printed circuit board inside of the connection box. The connection box optionally includes a metal plate mounted inside the lid of the connection box as a heat sink for dissipating heat from the diodes.

The term “cable gland” as used herein refers to a device used for the entry of electrical cables or cords into electrical equipment and is used to firmly secure an electrical cable entering a piece of electrical equipment.

The term “in situ” in the context of the present invention refers to bonding or attaching during manufacture, e.g. injection molding, of a part as opposed to attaching after manufacture of the part.

### BRIEF SUMMARY

According to an aspect of the present invention there is provided a junction box used for making electrical connections to a photovoltaic panel. The junction box has two chambers including a first chamber and a second chamber and a wall common to and separating both chambers. The wall may be adapted to have an electrical connection therethrough. The two lids are adapted to seal respectively the two chambers. The two lids are configured to be on opposite sides of the junction box relative to the photovoltaic panel. The two lids may be attachable using different sealing processes. One of the lids may be adapted to seal the first chamber and the other lid may seal the second chamber to a different level of hermeticity from that of the first chamber. The first chamber may be adapted to receive a circuit board for electrical power conversion of the power output of the photovoltaic panel. The junction box may include supports for mounting a printed circuit board in the first chamber. The second chamber is configured for electrical connection to the photovoltaic panel. The second chamber may optionally be configured to include diodes, e.g. bypass and/or blocking diodes. The junction box may have electrical connection terminals mounted inside the second chamber for connecting a circuit to the photovoltaic panel. A metal heat sink may be bonded inside the first chamber. The first chamber is adapted to receive a circuit board for electrical power conversion, and the metal heat sink is adapted to dissipate heat generated by the circuit board. The heat sink is placed inside an injection mold during manufacture of the junction box. The junction box may further include a pad adapted to provide thermal conduction and electrical insulation between the circuit board and the metal heat sink. The metal heat sink may include a dovetail structure adapted to prevent mutual separation of the metal heat sink from the junction box. The dovetail structure may be hollow.

According to an aspect of the present invention there is provided a junction box used for making electrical connections to a photovoltaic panel. The junction box has a metal heat sink bonded in situ inside the first chamber. The first chamber is adapted to receive a circuit board for electrical power conversion, and the metal heat sink is adapted to dissipate heat generated by the circuit board. The junction box optionally may have two chambers including a first chamber and a second chamber and a wall common to and separating both chambers. Two lids may be adapted to seal respectively the two chambers. The metal heat sink may include a dovetail structure adapted to prevent mutual separation of the metal heat sink from the junction box. The wall may have an electrical connection therethrough.

### BRIEF DESCRIPTION OF THE DRAWINGS

Aspects of the invention are herein described, by way of example only, with reference to the accompanying drawings, wherein:

FIGS. 1A and 1B illustrate isometric views of a junction box, according to an embodiment of the present invention.

FIG. 2A shows details of cross section of the junction box indicated by dotted line XX in FIG. 1A.

FIG. 2B shows details of cross section YY of the junction box indicated by dotted line in FIG. 1A.

FIGS. 3A and 3B show isometric views of a heat sink according to another embodiment of the present invention.

The foregoing and/or other aspects will become apparent from the following detailed description when considered in conjunction with the accompanying drawing figures.

### DETAILED DESCRIPTION

Reference will now be made in detail to embodiments of the present invention, examples of which are illustrated in the accompanying drawings, wherein like reference numerals refer to the like elements throughout. The embodiments are described below to explain the present invention by referring to the figures.

By way of introduction, diodes and/or electronic modules within junction boxes attached to the photovoltaic modules dissipate heat. When insulating junction boxes are used, heat must be dissipated mostly through air inside the junction box. When metallic junction boxes are used then heat may be dissipated directly through the junction box. However, the use of a metallic junction boxes may be inconvenient because of regulations which require accessible metallic surfaces to be grounded and extra wiring is required.

Before explaining exemplary embodiments of the invention in detail, it is to be understood that the invention is not limited in its application to the details of design and the arrangement of the components set forth in the following description or illustrated in the drawings. The invention is capable of other embodiments or of being practiced or carried out in various ways. Also, it is to be understood that the phraseology and terminology employed herein is for the purpose of description and should not be regarded as limiting.

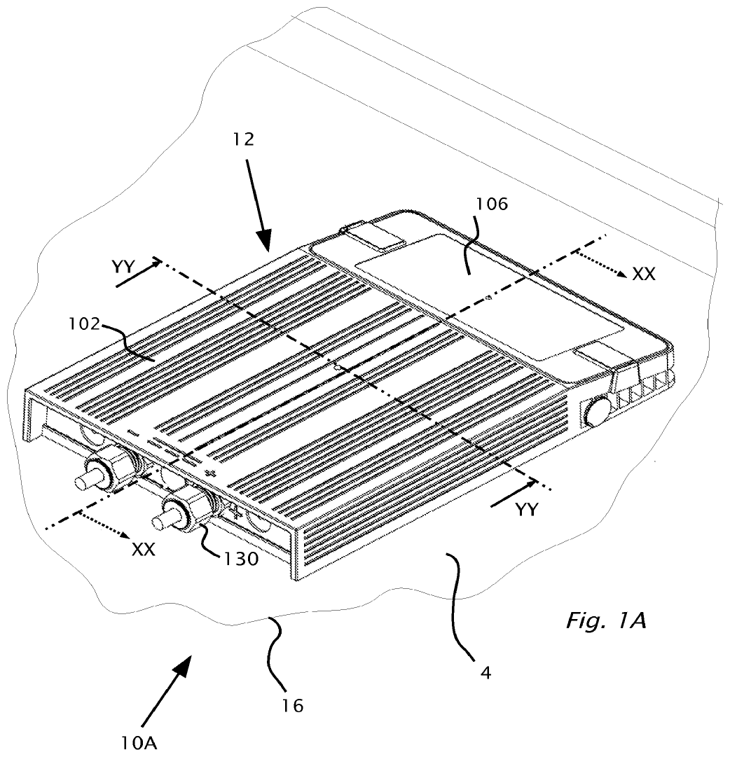

Referring now to the drawings, FIG. 1A shows an isometric view 10A of a junction box 12, according to an embodiment of the present invention. Junction box 12 is shown mounted on the back (or non-photovoltaic side) 4 of a photovoltaic panel 16. Junction box 12 has cable glands 130 which allow for termination of cables inside of junction box 12. Junction box 12 has an outer casing 102 and an access into junction box 12 using a lid 106.

FIG. 1B shows an isometric view of the underside of junction box 12 detached from photovoltaic panel 16. The isometric view shows glands 130 and two sections A and B of junction box 12. chamber A is bounded by the dimensions Z×X with chamber A covered by lid 108. Lid 108 gives access into chamber A of junction box 12. Chamber B is an open section which is bounded by dimensions X×Y and shows terminals 104. A bypass diode 110 is connected between terminals 104. According to a feature of the present invention, lid 106 removed to access chamber B and lid 108 used to access chamber A are on opposite sides of junction box 12.

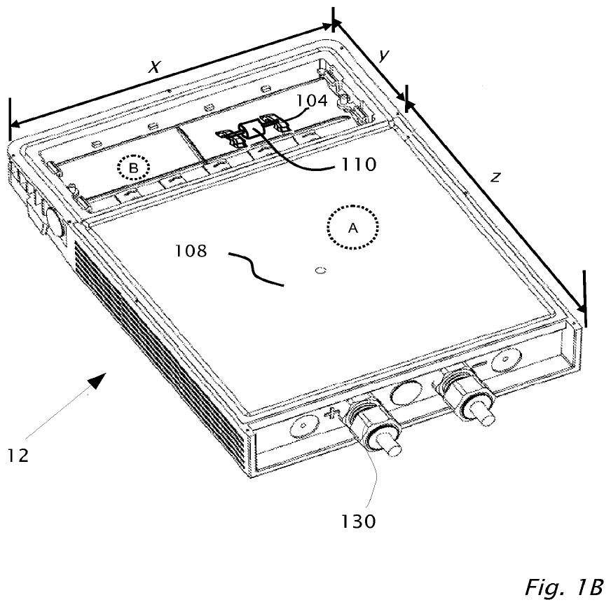

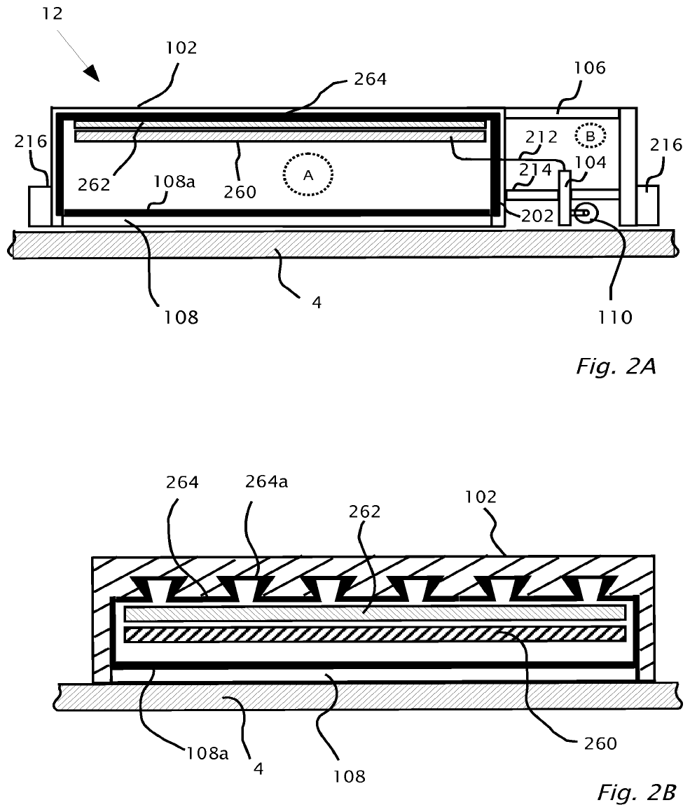

FIG. 2A shows details of cross section XX of junction box 12 indicated by dotted line in FIG. 1A, showing features of the present invention. Cross section XX shows chamber sections A and B of junction box 12 mounted on non-photovoltaic side 4 of photovoltaic panel 16 with clips 216. The mechanical attachment between junction box 12 and photovoltaic panel 16 using clips 216 is such that junction box 12 is flat on photovoltaic panel 16 and a gasket may be used to seal the open end of chamber B.

Chamber A includes circuit board 260, thermally conductive pad 262, heat sink 264, outer casing 102 and lid 108. Circuit board 260 is preferably mounted on supports adapted to receive circuit board 260. Thermal pad 262 provides electrical isolation and thermal conductivity between heat sink 264 and circuit board 260. The component side of circuit board 260 is preferably in contact with thermal pad 262 so that heat created by the components of circuit board 260 is dissipated by heat sink 264 via thermal pad 262. Radio Frequency Interference (RFI) emission from junction box 12 as a result of the operation of circuit board 260 is reduced by having the side of lid 108 coated in an electrically conductive shielding 108a. Shielding 108a connects electrically to heat sink 264 to form a Faraday cage which suppresses RFI emission from junction box 12.

Lid 108 according to an aspect of the present invention is preferably manufactured by an injection molding process. During the injection molding process of lid 207 a shield 108a may be placed in situ and bonded to lid 108 during the injection molding process. Thus, when lid 108 is attached to box chamber A; junction box 12 is electrically isolated by heat sink 264 and shield 108a. Outer casing 102 and lid 108 additionally provide a non-electrically conductive isolation of heat sink 264 and shield 108a between the backside 4 of panel 16 and the exterior of junction box 12. Lid 108 is optionally permanently and/or hermetically sealed to chamber A.

Chamber B includes terminal 104, support 214, bypass diode 110, lid 106, bus bar 212 and wall 202. Wall 202 provides physical separation between chambers A and B. Electrical connectivity between circuit board 260 in chamber A and electrical connector 104 in chamber B is via bus bar 212. Bus bar 212 is sealed in wall 202 in such a way as to preserve the desired hermeticity of chamber A for example against the ingress of water or humidity. Both electrical connector 104 and bus bar 212 are supported mechanically by support 214. Support 214 may also provide hermetic sealing and/or electrical isolation between one end of connector 104 which connects to bus bar 212 and the other end of connector 104 which connects to connections provided by photovoltaic panel 16. Bypass diode 110 connected to connector 104 may be located between support 214 or backside 4 of panel 16 or between support 214 and lid 106. Lid 106 gives access to chamber B whilst junction box 12 is physically attached photovoltaic panel 16 but electrically isolated from panel 16. A preferred mechanism of attaching lid 106 to junction box 12 is to use a rubber gasket arrangement such that chamber B is hermetically sealed against for example the ingress of water/humidity through lid 106 into chamber B.

According to another embodiment of the present invention, junction box 12 is constructed with a wall 202 that may be a double wall so that chamber A and chamber B are mutually separable and re-attachable. Similarly, bus bar 212 is re-connectable between chamber A and chamber B. In this embodiment, a failure within the electronics of circuit board 260 may be repaired by replacing chamber A with a new circuit board 260 without requiring disconnection of chamber B from photovoltaic panel 16. Similarly, an electronics upgrade may be easily achieved.

Junction box 12 including casing 102, lids 108/106, heat sink 264, and thermal pad 262 are preferably adapted to comply with temperature and insulation standard of IEC 61215 (Ed. 2) or other applicable industry standards for use with connection to photovoltaic panels. Junction box 12 and lids 108/106 may be manufactured by injection molding of acrylonitrile butadiene styrene (ABS) thermoplastic, Polybutylene terephthalate (PBT), Poly(p-phenylene oxide) (PPO) or a thermoset such as epoxy resin.

FIG. 2B shows details of cross section YY of junction box 12 indicated by dotted line in FIG. 1A, according to an embodiment of the present invention. Cross section YY is of chamber A mounted on backside 4 of photovoltaic panel 16. Cross section YY shows outer casing 102, heat sink 264 with dovetail structure 264a, thermally conductive pad 262, circuit board 260 and lid 108 with electrical shield 108a.

The manufacture of box chamber sections A and B of junction box 12 in a preferred embodiment of the present invention is by an injection molding process. During the injection molding process heat sink 264 with or without dovetail structure 264a is placed inside box chamber A and is bonded in situ to box chamber A as a result of the injection molding process.

Additional strength of the bonding between heat sink 264 and box chamber A may be provided by a dovetail structure 264a which may be an integral part of heat sink 264. A further function of dovetail structure 264a ensures that the bonding between heat sink 264 and chamber A remains intact when for example junction box 12 is subjected to thermal stresses as a result of electronic components operating inside chamber A, high ambient heat and sunlight when junction box 12 attached to a photovoltaic panel. Where a fastener, e.g. screw is used to fasten chamber A to heat sink 264, the lateral dimensions of dovetail structure 264a is typically increased in order to accommodate the size of the fastener. A further feature of dovetail structure 264a is a hollow structure within dovetail structure 264a which allows for a deformation of dovetail structure 264a. The deformation of dovetail structure 264a allows for the different rates of thermal expansion of enclosure 102 and heat sink 264/dovetail structure 264a during the curing/cooling of the bond between heat sink 264 and enclosure 102 of chamber A.

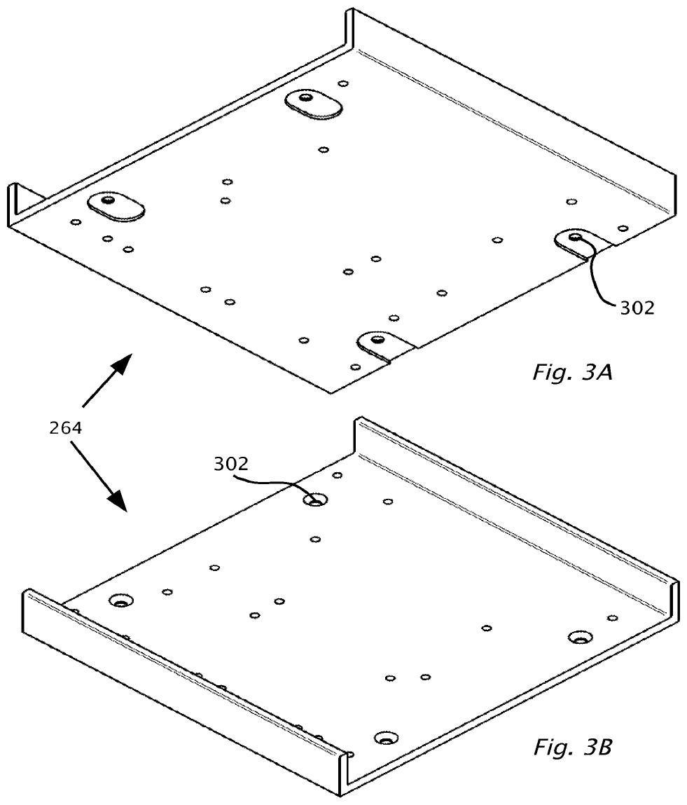

Reference is now made to FIGS. 3A and 3B which show isometric views of heat sink 264 according to another embodiment of the present invention. Heat sink 264 has four holes 302. Holes 302 are used to attach heat sink 264 into chamber A of junction box 12 using screws. The attachment of heat sink to chamber A may come as an additional step after the injection molding of junction box 12 or of a junction box 12 which is not injection molded. An additional thermal pad may be placed between heat sink 264 and enclosure 102 to ensure good contact between heat sink 264 and enclosure 102 after heat sink 264 is attached enclosure 102. The deformable nature of the thermal pad used to accommodate non-uniformity in surfaces of the heat sink 264 and enclosure 102 due to manufacturing tolerances of heat sink 264/enclosure 102. Alternatively a thermally conducting glue or potting material may be placed between heat sink 264 and enclosure 102.

The articles “a” “an” as used herein mean “one or more” such as “a heat-sink”, “a circuit board” have the meaning of “one or more” that is “one or more heat-sinks” or “one or more circuit boards”.

Although selected embodiments of the present invention have been shown and described, it is to be understood the present invention is not limited to the described embodiments. Instead, it is to be appreciated that changes may be made to these embodiments without departing from the principles and spirit of the invention, the scope of which is defined by the claims and the equivalents thereof.

1. An apparatus comprising:
an enclosure comprising a lid therein defining a chamber; and
a shield bonded to the lid and the enclosure, wherein the shield comprises an electrically conductive shielding, wherein the shield forms a Faraday cage, and wherein the Faraday cage is configured to suppress Radio Frequency Interference (RFI) emission from the apparatus.

2. The apparatus according to claim 1, further comprising a heat sink, wherein the heat sink connects electrically to the shield to form the Faraday cage.

3. The apparatus according to claim 2, wherein the enclosure comprises at least a portion of the heat sink.

4. The apparatus according to claim 2, wherein the heat sink comprises a dovetail structure and the dovetail structure is integrated with the enclosure.

5. The apparatus according to claim 1, further comprising a second enclosure defining a second chamber.

6. The apparatus according to claim 5, further comprising a wall separating the chamber and the second chamber.

7. The apparatus according to claim 5, wherein the second enclosure comprises a second lid.

8. The apparatus according to claim 7, wherein the lid and the second lid are attached to the apparatus using different sealing processes configured to create different levels of hermeticity in the chamber and in the second chamber.

9. The apparatus according to claim 7, wherein the lid and the second lid are disposed on opposite sides of the apparatus.

10. The apparatus according to claim 5, wherein the second chamber comprises a bypass diode.

11. The apparatus according to claim 5, wherein the second chamber comprises a blocking diode.

12. The apparatus according to claim 6, wherein the enclosure is separable and re-attachable, wherein the second enclosure is separable and re-attachable, or the enclosure and the second enclosure are separable and re-attachable.

13. The apparatus according to claim 1, wherein the chamber comprises a thermally conductive pad, and wherein the thermally conductive pad is electrically isolating.

14. The apparatus according to claim 1, wherein the shield is compliant with the International Electrotechnical Commission (IEC) 61215 second edition standard.

15. The apparatus according to claim 1, wherein the lid comprises a coating of an electrically conductive material.

16. The apparatus according to claim 1, wherein the chamber comprises a circuit board.

17. The apparatus according to claim 1, wherein the chamber comprises an outer casing.

18. The apparatus according to claim 1, wherein the apparatus is configured to be mounted on a non-photovoltaic side of a photovoltaic panel.

19. A system comprising:
a plurality of photovoltaic panels connected in a serial string;
a central inverter connected to the serial string; and
a plurality of junction boxes, wherein each junction box of the plurality of junction boxes is attached to a photovoltaic panel of the plurality of photovoltaic panels, and comprises:
an enclosure comprising a lid therein defining a chamber; and
a shield bonded to the lid and the enclosure, wherein the shield comprises an electrically conductive shielding, wherein the shield forms a Faraday cage, and wherein the Faraday cage is configured to suppress Radio Frequency Interference (RFI) emission from the junction box.

20. The system according to claim 19, wherein each junction box comprises a heat sink, and wherein the heat sink connects electrically to the shield to form the Faraday cage.
